(19) United States
(12) Patent Application Publication
(10) Pub. No.: US 2008/0074844 A1
(43) Pub. Date: Mar. 27, 2008

(54) Heat pipe structure

(76) Inventor: Been-Yu Liaw, Jhongli City (TW)

Correspondence Address: Troxell Law Office Pllc, Suite 1404, 5205 Leesburg Pike, Falls Church, VA, 22041, US

(21) Appl. No.: 11/526,079

(22) Filed: Sep. 25, 2006

(51) Int. Cl. H05K 7/20

(52) U.S. Cl. 361/702; 361/700

(57) ABSTRACT

A heat pipe structure is composed of a heat pipe, a heat dissipation plate, a heat source member, and screws, wherein the heat pipe is transfixed into the heat dissipation plate, heated, and extruded, such that an end of the heat pipe is molten at a slant cut of the heat dissipation plate, enabling the heat dissipation plate and the heat pipe to be molten into one body. Next, the heat dissipation plate and the heat pipe are processed with a CNC (Computer Numerical Control) machine to form into a complete plane, and the screws are used to lock the heat source member on the heat dissipation plate, such that heat energy is effectively absorbed by the heat transmission structure, and is transmitted out through the heat pipe.

### BACKGROUND OF THE INVENTION

(a) Field of the Invention

The present invention relates to a heat pipe structure, and more particularly to a heat pipe structure used for transmitting heat energy, which includes a heat pipe that is transfixed into a heat dissipation plate for melting and compression, as well as for being processed with a CNC (Computer Numerical Control) machine, so as to increase a smoothness of a location for transmitting the heat source, thereby achieving the best heat transmission function for the heat transmission structure.

(b) Description of the Prior Art

A conventional heat pipe is embedded into a heat dissipation plate, and an end of the heat pipe is a round-shape end which is corresponding to the heat dissipation plate. The round-shape end and the heat dissipation plate are used as a medium for transmitting heat source. However, as the round-shape end and the heat dissipation plate do not form into a complete plane, a heat transmission surface being contacted by a substrate, heat of which is to be dissipated, will not be uniform, such that the heat energy created by the substrate cannot be effectively transmitted to the heat dissipation plate, and the heat source which is absorbed by the heat dissipation plate cannot be effectively dissipated through the heat transmission of heat pipe, at a same time.

Accordingly, how to eliminate the aforementioned problems is a technical issue to be solved by the present inventor.

### SUMMARY OF THE INVENTION

The primary object of present invention is to provide a heat pipe structure which is used to transmit heat energy.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a perspective view of the present invention.

FIG. 2 shows an exploded view of the present invention.

FIG. 3 shows a schematic view of an embodient of the present invention.

FIG. 4 shows a second schematic view of an embodient of the present invention.

FIG. 5 shows a third schematic view of an embodient of the present invention.

FIG. 6 shows a fourth schematic view of an embodient of the present invention.

FIG. 7 shows a fifth schematic view of an embodient of the present invention.

FIG. 8 shows a sixth schematic view of an embodient of the present invention.

### DETAILED DESCRIPTION OF THE PREFERRED EMBODIMENTS

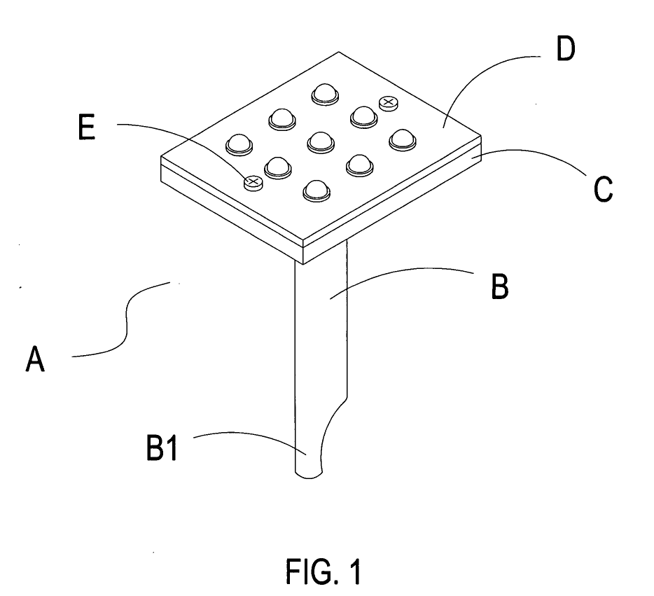

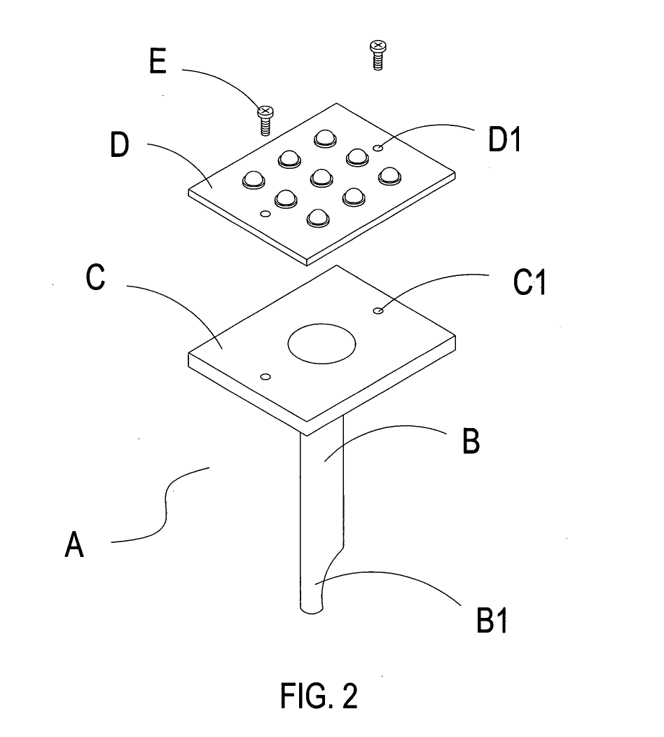

The present invention is to provide a heat pipe structure. Referring to FIG. 1 and FIG. 2, a heat transmission structure A comprises primarily a heat pipe B, a heat dissipation plate C, a heat source member D, and screws E, wherein the heat dissipation plate C is opened with a plurality of screw-holes C1, and an interior of the heat dissipation plate C is transfixed with the heat pipe B, an end of which is corresponding to a surface of the heat dissipation plate C, and the other end of which is provided with a seal B1, such that heat source absorbed by the heat dissipation plate C can be effectively transmitted.

The heat dissipation plate C is installed with the heat source member D on which is provided with a plurality of through-holes D1 which are corresponding to the plural screw-holes C1 on the heat dissipation plate C. The plural through-holes D1 are transfixed respectively with the screws E which are locked into the screw-holes C1 for being tightly fixed.

The heat pipe B of heat transmission structure A is transfixed into the heat dissipation plate C, heated, and extruded, such that an end of the heat pipe B is melted at the heat dissipation plate C, and a coherence between the heat dissipation plate C and the heat pipe B is increased. On the other hand, the heat source absorbed by the heat source member D on the heat dissipation plate C is transmitted by the heat pipe B, such that the heat source generated by the heat source member D is effectively transmitted by the heat transmission structure A, and is effectively dissipated by the heat pipe B.

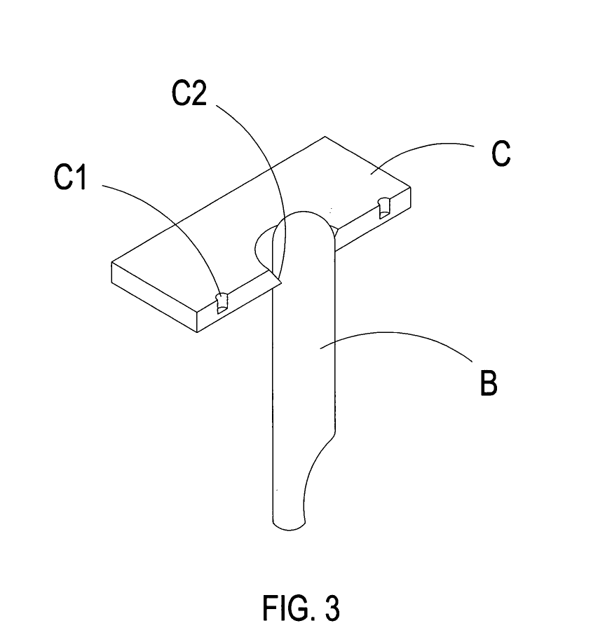

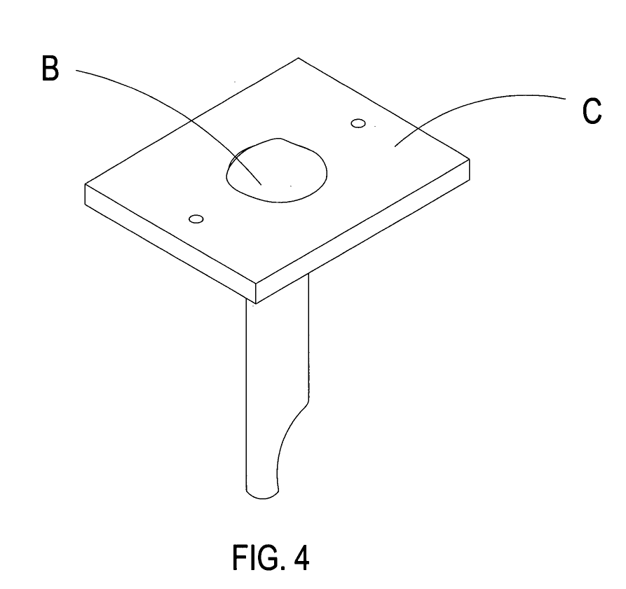

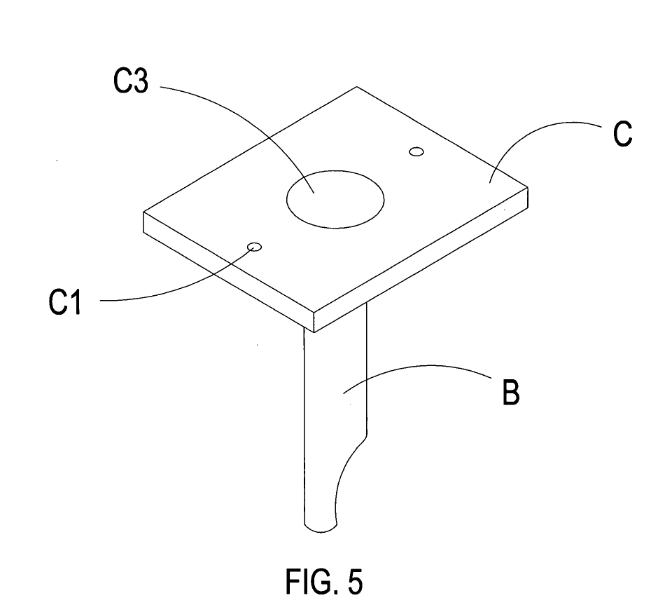

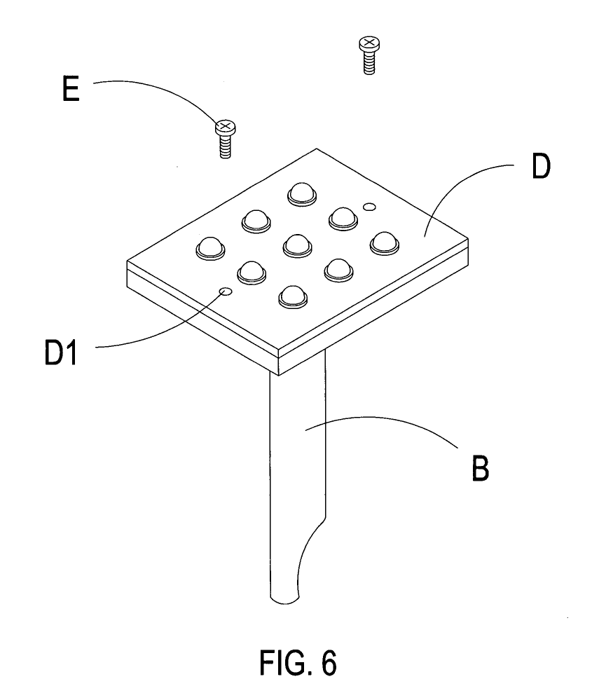

Referring to FIGS. 3 to 6, the heat dissipation plate C is transfixed with the heat pipe B, and is provided with a slant cut C2 at a position corresponding to the heat pipe B. When the heat pipe B is heated and extruded, the heat pipe B will be melted at the slant cut C2, and through a filling of the molten heat pipe B into the slant cut C2, the heat pipe B and the heat dissipation plate C are fused into one body and form into a plane C3. Next, the heat dissipation plate C and the heat pipe B are processed with a CNC (Computer Numerical Control) machine, so as to increase a smoothness of the plane C3, thereby forming into a complete plane C3. Accordingly, the heat source member D can be emplaced on the plane C3, and the screws E are transfixed into the through-holes D1 of heat source member D to be tightly locked into the screw-holes C1 on the heat dissipation plate C, such that the heat source member D is firmly affixed on the heat dissipation plate C to effectively transmit the heat source to the heat dissipation plate C, and the heat source absorbed by the heat dissipation plate C is dissipated through the heat pipe B.

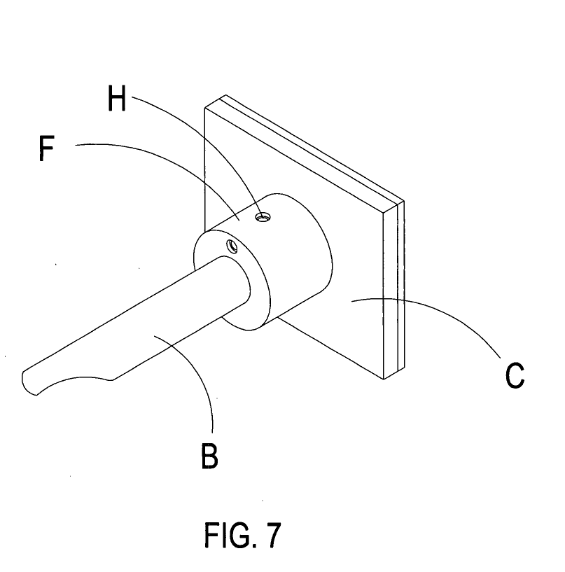

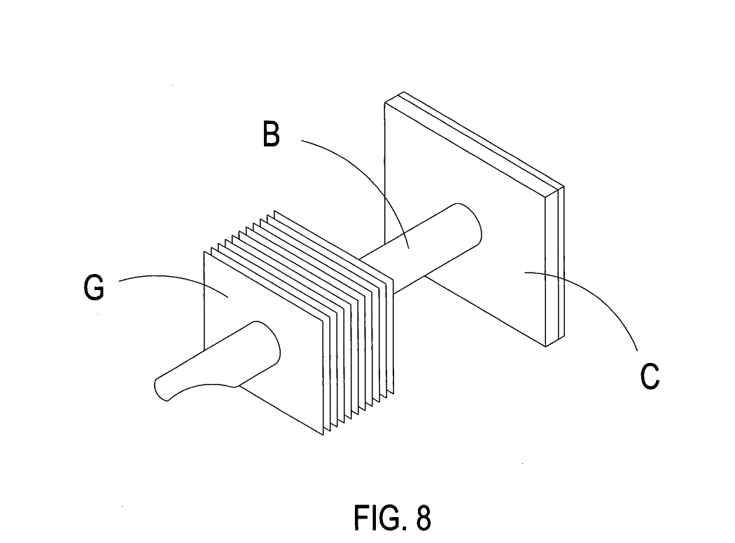

Referring to FIG. 7 and FIG. 8, a heat transmission block F is further installed between the heat dissipation plate C and the heat pipe B to increase a passage of heat transmission from absorption of the heat source by the heat dissipation plate C to the heat pipe B. The heat transmission block F is also provided with a plurality of screw-holes H which provide for a locking of an externally connected heat dissipation device and a device with heat of which being dissipated. In addition, the other end of heat pipe B is further provided with fins G which provide for an efficient dissipation of the heat source absorbed by the heat pipe B, wherein the heat dissipation plate C and the heat transmission block F are further made by a copper material, an aluminum material, an alloy material, a ceramic material, and other related material that is provided with a high heat transmission effect.

To further manifest the advancement and practicability of the present invention, the present invention is compared with a conventional heat pipe structure as follow:

Shortcomings of a Conventional Heat Pipe Structure
1. The connecting plane between the round-shape end of heat pipe and the heat dissipation plate does not form into a complete plane.
2. According to item 1, the heat transmission surface being contacted by a substrate, heat of which is to be dissipated, is not uniform, and the heat cannot be transmitted effectively.
3. The heat source absorbed by the heat dissipation plate cannot be effectively transmitted out by the heat pipe.

### ADVANTAGES OF THE PRESENT INVENTION

1. The heat pipe is molten on the heat dissipation plate and is processed with the CNC (Computer Numerical Control) machine, to form into the complete plane.
2. According to item 1, the plane can effectively absorb the heat source generated by the heat source member.
3. The heat source absorbed by the heat dissipation plate can be effectively transmitted out by the heat pipe.
4. It has the advancement and practicability.
5. It can improve an industrial competitiveness.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A heat pipe structure comprising a heat pipe, which is used to transmit heat energy generated by a heat source member, and an end of which is provided with a seal; a heat dissipation plate, which is used to absorb the heat energy generated by the heat source member, is transfixed with the heat pipe, and a surface of which is opened with a plurality of screw-holes; the heat source member, which is installed on the heat pipe and the heat dissipation plate, transmits the heat source through a contact surface between the heat pipe and the heat dissipation plate, and is provided with a plurality of through-holes which are corresponding to the plurality of screw-holes; and a plurality of screws, which are transfixed into the plural through-holes of heat source member, and are locked into the plural screw-holes on the heat dissipation plate for being tightly fixed.

2. The heat pipe structure according to claim 1, wherein the heat pipe is transfixed into the heat dissipation plate, heated, and extruded, such that an end of the heat pipe is molten at a slant cut of the heat dissipation plate, thereby enabling the heat pipe and the heat dissipation plate to be formed into a plane, in order to achieve the best heat transmission effect.

3. The heat pipe structure according to claim 2, wherein the plane is further processed with a CNC (Computer Numerical Control) machine, a lathe, a punch, an electroforming machine, a laser machine, an electric discharge machine, an injection molding machine, and other related method or device that is used to increase a smoothness of the plane.

4. The heat pipe structure according to claim 1, wherein a heat transmission block is further installed between the heat dissipation plate and the heat pipe, in order to increase a passage of heat transmission from absorption of the heat source by the heat dissipation plate to the heat pipe.

5. The heat pipe structure according to claim 4, wherein the heat transmission block includes a plurality of screw-holes which provide for a locking of an externally connected heat dissipation device and a device with heat of which being dissipated.

6. The heat pipe structure according to claim 1, wherein the other end of the heat pipe is further provided with fins, such that the heat transmission structure dissipates effectively the heat source absorbed.

7. The heat pipe structure according to claim 1, wherein the heat source member is further an integrated circuit, a CPU (Central Processing Unit), a storage device, an illumination device, a transformer, and other related device that generates heat.

8. The heat pipe structure according to claim 1, wherein the heat dissipation plate is further made by a copper material, an aluminum material, an alloy material, a ceramic material, and other material that is provided with a high heat transmission effect.

9. The heat pipe structure according to claim 4, wherein the heat pipe is further made by a copper material, an aluminum material, an alloy material, a ceramic material, and other material that is provided with a high heat transmission effect.
